(19) United States
(12) Patent Application Publication
(10) Pub. No.: US 2025/0107147 A1
(43) Pub. Date: Mar. 27, 2025

(54) ARCHITECTURES AND METHODS TO MODULATE CONTACT RESISTANCE IN 2D MATERIALS FOR USE IN FIELD EFFECT TRANSISTOR DEVICES

(71) Applicant: Intel Corporation, Santa Clara, CA (US)

(72) Inventors: Mahmut Sami Kavrik, Eugene, OR (US); Uygar E. Avci, Portland, OR (US); Pratyush P. Buragohain, Hillsboro, OR (US); Chelsey Dorow, Portland, OR (US); Jack T. Kavalieros, Portland, OR (US); Chia-Ching Lin, Portland, OR (US); Matthew V. Metz, Portland, OR (US); Wouter Mortelmans, Portland, OR (US); Carl Hugo Naylor, Portland, OR (US); Kevin P. O'Brien, Portland, OR (US); Ashish Verma Penumatcha, Hillsboro, OR (US); Carly Rogan, North Plains, OR (US); Rachel A. Steinhardt, Beaverton, OR (US); Tristan A. Tronic, Aloha, OR (US); Andrey Vyatskikh, Hillsboro, OR (US)

(73) Assignee: Intel Corporation, Santa Clara, CA (US)

(21) Appl. No.: 18/476,248

(22) Filed: Sep. 27, 2023

(51) Int. Cl. H01L 29/786; H01L 21/02; H01L 21/46; H01L 27/092; H01L 29/24; H01L 29/51; H01L 29/66; H01L 29/76

(52) U.S. Cl. CPC H10D 30/6713; H01L 21/02568; H01L 21/46; H10D 30/6757; H10D 48/362; H10D 62/80; H10D 64/689; H10D 84/85; H10D 99/00

(57) ABSTRACT

Hybrid bonding interconnect (HBI) architectures for scalability. Embodiments implement a bonding layer on a semiconductor die that includes a thick oxide layer overlaid with a thin layer of a hermetic material including silicon and at least one of carbon and nitrogen. The conductive bonds of the semiconductor die are placed in the thick oxide layer and exposed at the surface of the hermetic material. Some embodiments implement a non-bonding moisture seal ring (MSR) structure.

### BACKGROUND

Contact resistance of a field effect transistor (FET) refers to the resistance measured at the interface between a source region of the channel material and a contact metal on source region as well as between a drain region of the channel material and a contact metal on the drain region. Contact resistance directly impacts the performance of the transistor and determines the maximum drive current and clock frequency achievable by devices utilizing FETs.

### BRIEF DESCRIPTION OF THE DRAWINGS

FIGS. 1A, 1B, 1C, 2A, and 2B, are simplified cross-sectional diagrams showing stages of fabrication of various embodiments of transistor architecture described herein.

FIG. 3 is a simplified cross-sectional diagram showing another exemplary stage of fabrication of various embodiments of the transistor architecture described herein.

FIG. 4 is a simplified cross-sectional diagram of an embodiment of a transistor architecture with the doped source and drain regions having source and drain contact metal added thereto, in accordance with various embodiments described herein.

FIG. 5 illustrates an example method for manufacturing various embodiments described herein.

FIG. 6A is a perspective view of an exemplary planar field effect transistor (FET) that may implement the transistor architecture described herein.

FIG. 6B is a cross-sectional view of the planar FET taken along the source contact region of transistor.

FIG. 7 is an isometric view of a ribbon field-effect transistor (FET) that may implement the transistor architecture described herein.

FIG. 8A is a top view of the transistor of FIG. 7.

FIG. 8B is a cross-sectional side view of the transistor of FIG. 7.

FIG. 9 is a top view of a wafer and dies that may be included in a microelectronic assembly, in accordance with any of the embodiments disclosed herein.

FIG. 10 is a simplified cross-sectional side view showing an implementation of an integrated circuit on a die that may be included in various embodiments, in accordance with any of the embodiments disclosed herein.

FIG. 11A to FIG. 11D are simplified perspective views of example planar, FinFET, gate-all-around, and stacked gate-all-around transistors, as may be implemented in various embodiments.

FIG. 12 is a cross-sectional side view of a microelectronic assembly that may include any of the embodiments disclosed herein.

FIG. 13 is a block diagram of an example electrical device that may include any of the embodiments disclosed herein.

### DETAILED DESCRIPTION

Complementary metal oxide semiconductor (CMOS) technology nodes may be characterized by the performance of the respective Field Effect Transistor (FET) drain currents (Ips) and gate to source voltages (Vas). Additionally, FET performance is impacted by contact resistance, which directly impacts the performance of a transistor and determines the maximum drive current and clock frequency achievable in devices utilizing these transistors. As used herein, “contact resistance” is a resistance measured at the interface between a source material and a source contact metal and/or between a drain material and a drain contact metal. Often, it is desirable to control the contact resistance in transistors to achieve transistor/device performance goals. However, suitably tailoring the contact resistance while not adversely affecting other performance targets is technically challenging.

With many CMOS transistors, the contact resistance is tailored by doping a semiconductor material that is several nanometer (nm) thick. The resulting doping can be classified into substitutional doping and interstitial doping. In case of substitutional doping, atoms of the host metal are replaced by different atoms, whereas interstitial doping involves introducing foreign atoms into the interstitial sites.

Some contemporary CMOS technology nodes seek to implement a two-dimensional (2D) material (also sometimes called a monolayer) because they possess unique electronic and physical properties considered for CMOS beyond silicon (Si) substrates. 2D materials can be 1-3 atoms thick and can have a thickness in a range of 0.7 nanometers (nm) to 2.8 nm+/−10%. Due to the reduced, often sub-nanometer, thickness of the 2D material, doping the 2D material to control contact resistance is inherently challenging. In addition to the technical challenge of doping 2D materials, material-inherent defects in 2D materials can also strongly affect their contact resistance. Therefore, the technical challenges to controlling the contact resistance with 2D materials may preclude implementation of 2D material in some high-performance field effect transistors (FETs) and ferroelectric FETs (FeFETs).

One proposed solution introduces dopants into the 2D materials. However, without control over or quantification of the material-inherent defects, this approach is difficult to manage. Another proposed solution, sometimes called “capping” or charge doping, introduces an oxide on the surface of the source/drain (S/D) region in the 2D material. However, creating a uniform coating of oxide on the 2D material to “cap” the S/D regions without also coating the channel region is technically challenging. Additionally, capping can introduce unwanted threshold voltage shifts as the fixed oxide charges of the caps interface with charge traps in the 2D material.

Accordingly, while the above approaches have made some improvements toward using 2D materials in FET devices, there is a need for architectures and methods to modulate contact resistance in 2D material for use in FET and FeFET devices.

Embodiments disclosed herein propose a technical solution to the above-described technical problems in the form of architectures and methods to modulate contact resistance in 2D material for use in field effect transistor devices. The method includes 1) intentionally forming vacancies in the 2D material in the S/D regions. A plasma can be used for this task; and 2) introducing dopants into the intentionally formed vacancies in the S/D regions. Plasma or gas can be used for this task as well. Plasma can uniformly dope 2D materials and plasma conditions can be precisely controlled, which can enable precise control of vacancy formation and subsequent doping of 2D materials. The proposed methodology resolves the S/D contact resistance problem with using 2D materials in high performance FET and FeFET devices. These concepts are developed in more detail below.

Aspects of the present disclosure may be discoverable using cross-sectional transmission electron microscopy (TEM) images and corresponding compositional analysis, such as Time of Flight Secondary Ion Mass Spectrometry (ToF SIMS), or electron energy loss spectroscopy (EELS) to reveal the stoichiometry and electronic structure. Additionally, the contact resistance, and certain performance targets and mobility measures, described in more detail below, can reveal that aspects of the present disclosure have been practiced.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

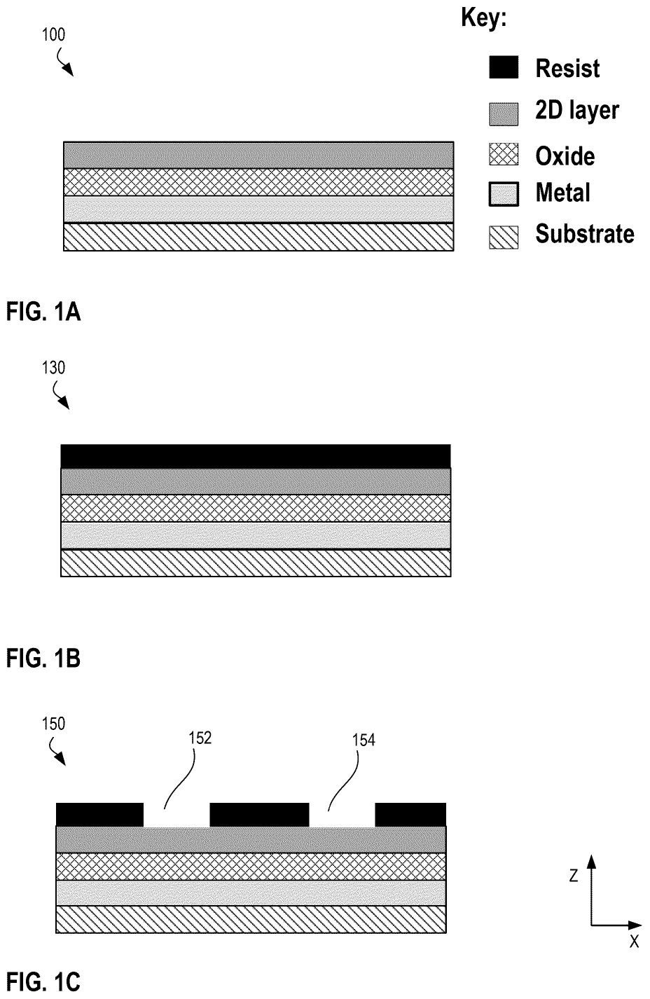

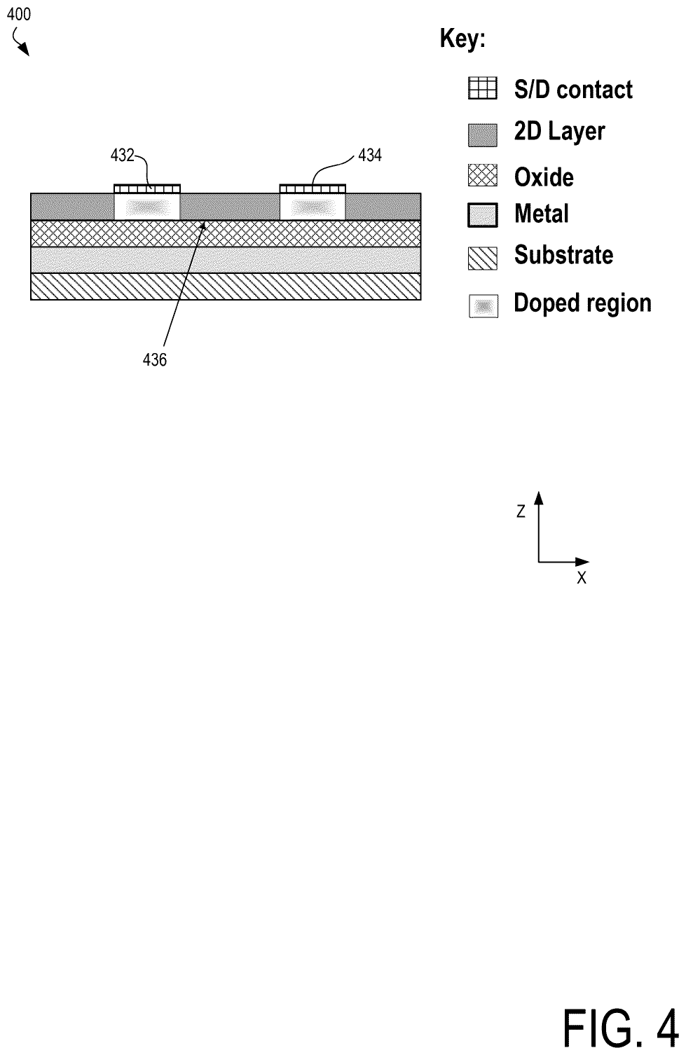

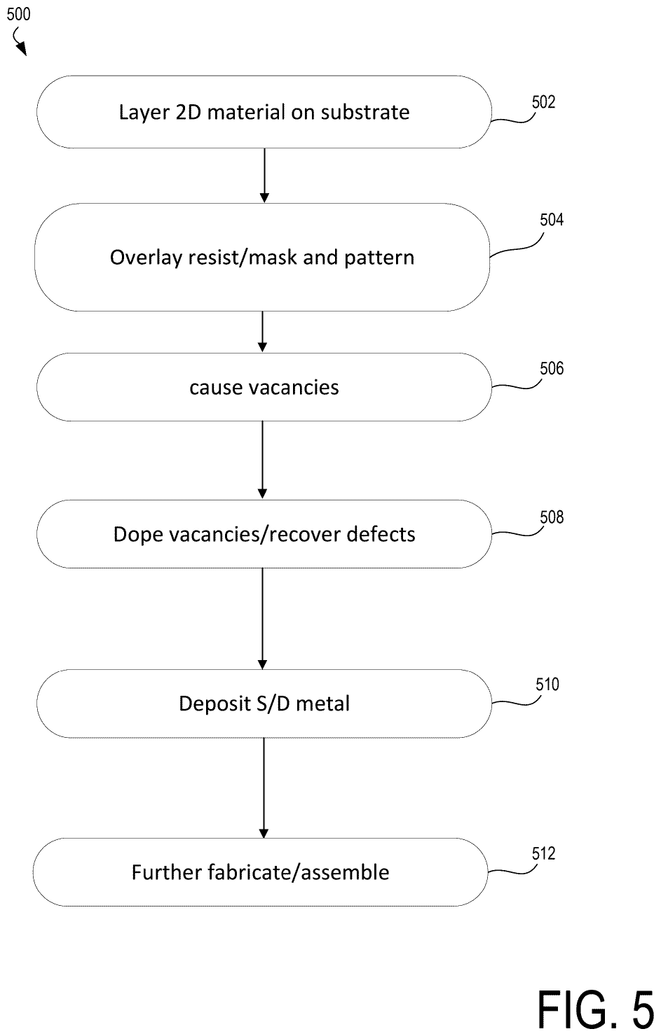

FIGS. 1A, 1B, 1C, 2A, 2B, 3, and 4 are simplified cross sectional diagrams showing some stages of fabrication of embodiments of a transistor architecture to modulate contact resistance in 2D material for use in field effect transistor devices, as described herein. FIG. 5 is a flowchart for an exemplary method for fabricating embodiments described herein. The method 500 may be executed by a technician and/or by one or more automated machines. In some embodiments, one or more machines may be programmed to do some or all of the steps of the method 500. Such a machine may include, e.g., a memory, a processor, data storage, etc. The memory and/or data storage may store instructions that, when executed by the machine, cause the machine to perform some or all of the steps of the method 500. In addition to techniques specifically referenced herein, the method 500 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, thermal treatments, etc.

Embodiment 100 shows a substrate layer at the bottom, followed by (moving upward in the figure, or in the +Z direction) a metal layer, and oxide layer. The substrate layer in the bottom layer position (diagonal lines) can be silicon. In other embodiments, the substrate layer may be, e.g., silicon oxide, gallium nitride, or other suitable material.

The metal layer on the substrate (light grey) is present to provide back-gating and can comprise a metal (e.g., platinum, palladium, tungsten, molybdenum, tantalum, copper, aluminum, nickel, cobalt, iron, gold, silver, or combinations thereof). The metal layer can be in a range from 5 nm+/−10% to 500 nm+/−10% thick.

The oxide layer between the metal interlayer and the 2D layer (hatched area in the figures) can comprise a suitable oxide, such as aluminum oxide (Al2O3), hafnium oxide (HfO2), zirconium oxide (ZrO2), aluminum-doped hafnium oxide, silicon-doped hafnium oxide, niobium-doped hafnium oxide, titanium-doped hafnium oxide, germanium-doped hafnium oxide, gallium-doped hafnium oxide, titanium dioxide, tantalum pentoxide, niobium pentoxide, silicon dioxide (SiO2), carbon-doped silicon dioxide, fluorine-doped silicon dioxide, hydrogen-doped silicon dioxide, or combinations thereof. In various embodiments, the oxide layer can have a thickness from 1 nm+/−10% to 5 nm+/−10%.

In some embodiments, the 2D material is patterned with lithography. In other embodiments, the oxide layer is patterned with lithography and the 2D material is grown only on the patterned areas of the oxide. Embodiments are understood to include a plurality of dedicated S/D regions, even though the images in the figures are simplified to just show one.

At 502, a 2D material (dark grey) is grown on an upper surface of the oxide layer, as shown. As mentioned, the 2D material may be in a range of 0.7 nm to 2.8 nm thick (this thickness is a function of the number of atoms per layer, with 0.7 nm representing one 2D layer). The 2D material is to be channel material as well as part of source and drain regions of a transistor architecture. In various embodiments, the 2D material may be a chalcogenide, and may further be a semiconducting dichalcogenide or a transition metal dichalcogenide (TMD). A TMD may be a semiconductor of type MC2, with M being a transition metal (e.g., Mo or W) and C being a chalcogen (e.g., S, Se, or Te). The 2D material may also comprise tungsten diselenide (WSe₂), Molybdenum diselenide (MoSe₂), Molybdenum ditelluride (MoTe₂), tungsten disulfide (WS₂), or the like.

In various embodiments, growing the 2D material (at 502) may be performed at the large wafer scale and/or be grown by chemical vapor deposition (CVD) or metal organic chemical vapor deposition (MOCVD) techniques. In various embodiments, the channel material will be referred to as a 2D material, but in practice it may be a monolayer (e.g., only one layer of the constituent atoms of the material) or a multi-layer (e.g., including up to a few layers of the constituent atoms of the material).

At 504, respective source/drain locations are identified for a plurality of field effect transistors, in the 2D channel material. In embodiment 130, a layer of resist or mask material is overlaid on the layer of 2D material (at 504), and then patterned (i.e., removed) at embodiment 150 as necessary to expose the regions of the 2D material that are intended/identified to be the source and drain (also referred to as a first S/D region 152 and a second S/D region 154).

At 506, vacancies are intentionally introduced in the 2D material at the S/D regions 152, 154. A plasma or gas may be used to cause the vacancies. Embodiment 200 depicts a first plasma/gas (with open arrowheads) directed at the upper surface of the resist and exposed S/D regions 152, 154. To realize the vacancies, the first plasma/gas can include (H) hydrogen, (NH3) nitrogen tetra hydride, (O2) oxygen, and (CF4) carbon tetrafluoride; this combination can scavenge the sulfur(S) or selenium (Se) atoms from the 2D materials.

Bubbles 202 are used in the image to depict vacancies caused by the first plasma/gas. At 508, the vacancies are doped with dopant atoms to recover the defects. Embodiment 230 depicts a second plasma/gas (with filled arrowheads) introducing dopant atoms, to create doped S/D regions (first doped S/D region 232, second doped S/D region 234). The second plasma/gas may vary depending on the specific 2D material. In one example, the 2D material is WSe2, and the second plasma/gas comprises nitric oxide (NOx) (p), phosphorous (P) (p), vanadium (V) (p), sulfur(S), or fluorine (F) (p). In another example, the 2D material is MoS2, and the plasma/gas includes niobium (Nb) (p) or tantalum (Ta) (p).

In other process flows, as depicted in embodiment 300, a single plasma/gas procedure is depicted, which employs a combined plasma/gas (e.g., a third plasma/gas, with double arrowheads, to distinguish from the above examples) to cause the vacancies and introduce the dopant atoms therein, concurrently. Embodiment 300 illustrates causing the vacancies at 506 and doping the vacancies at 508 occurring as a result of one plasma procedure. In one example, for a 2D material of WSe2, the third plasma/gas could include (H) hydrogen, (NH3) ammonia, (O2) oxygen, or (CF4) carbon tetrafluoride plus nitric oxide (NOx) (p), phosphorous (P) (p), vanadium (V) (p), sulfur(S), or fluorine (F) (p). In another example, for a 2D material of MoS2, the third plasma/gas could include (H) hydrogen, (NH3) ammonia, (O2) oxygen, or (CF4) carbon tetrafluoride plus niobium (Nb) (p) or tantalum (Ta) (p).

In other embodiments, at 508, atomic layer deposition can be used for 2D doping. For example, embodiments have doped WS2 with Nb using atomic layer deposition. Further, the dopant can be introduced into the 2D material during material growth such as Re doped WSe2 or Nb doped WSe2 in various compositional ratios.

In various embodiments, the doping at 508 manifests as less than 10% of the atomic structure of the 2D material. In some scenarios, the resulting doping is in a range of about 0.03% to 1%, wherein about means+/−10% of the base number.

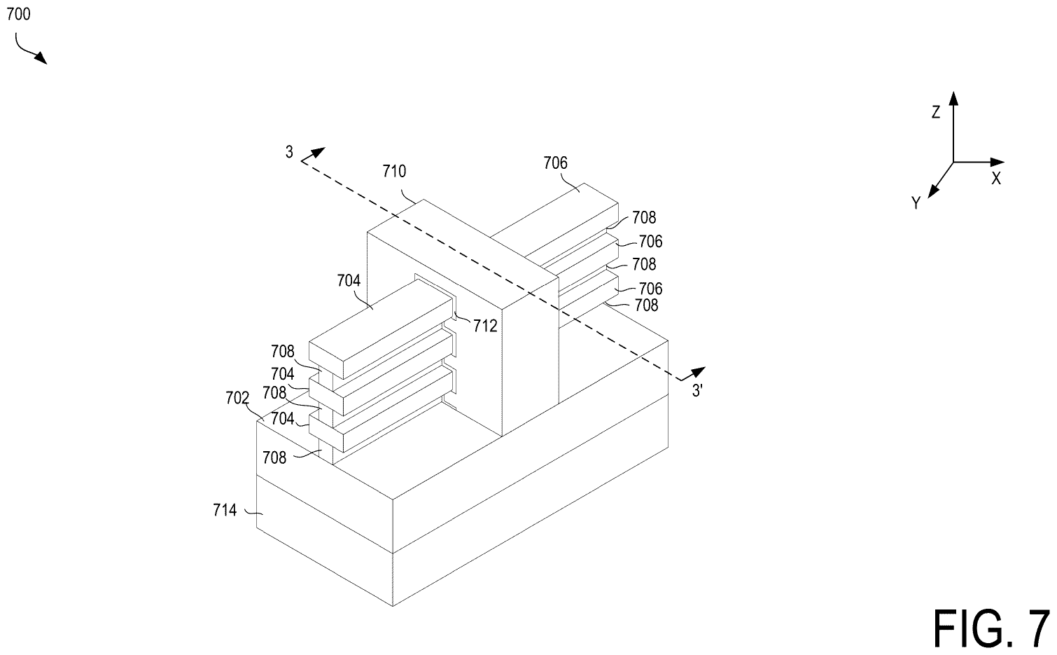

At 510 the S/D metal can be deposited, as indicated in embodiment 400. A layer of S/D contact metal can include a first S/D contact 432 and a second S/D contact 434. The S/D metal can include (e.g., antimony, bismuth, platinum, palladium, copper, aluminum, nickel, cobalt, iron, tin, gold, silver, or combinations thereof). In embodiments of FeFET devices, a ferromagnetic material may surround the channel, in the interface between the 2D channel material and the oxide (indicated with arrow 436 and described in more detail in connection with FIG. 7). At 512, embodiments with the above-described transistor architecture may be further fabricated or assembled into another device or package assembly. Accordingly, at 512, gate controls and material may be added, and singulation and assembly may be performed.

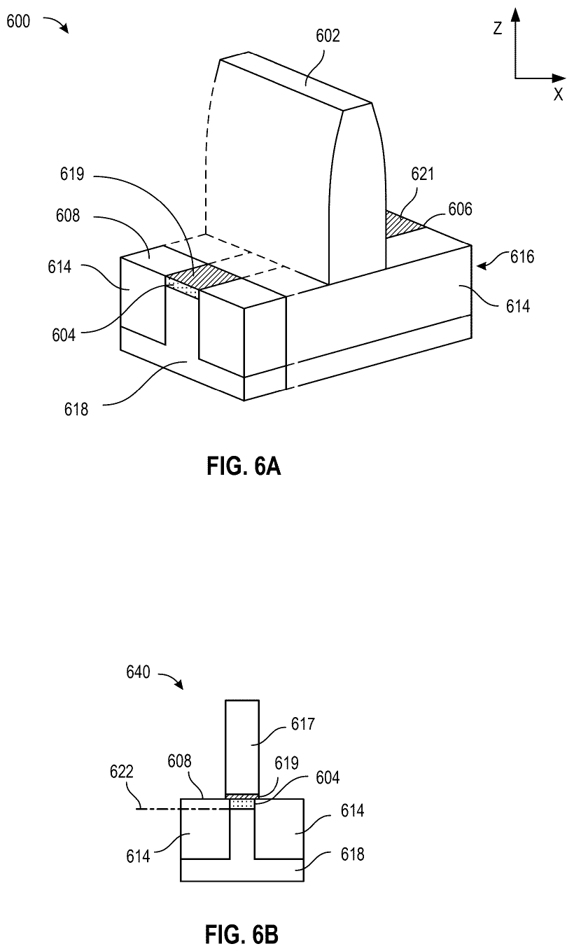

The contact resistance of the first S/D contact 432 and the second S/D contact 434 can be measured. In various embodiments, the contact resistance under the S/D metal will be less than 10 ohm/micrometer. In other embodiments, the contact resistance under the S/D metal will be less than 100 ohm/micrometer. Embodiments can be found in planar FETs, nanoribbon FETs, FeFETs, etc.; and further, these transistors can be found in a variety of package assemblies and devices, such as, central processing units (CPUs), graphics processing units (GPUs), artificial intelligence (AI) processing units, logic, memory components, etc. A variety of these structures are illustrated in FIGS. 6-13.

As mentioned above, in addition to the improved contact resistance and distinct compositional analysis, transistors that practice the architectures/compositions disclosed herein can be identified by their notable transistor performance improvements (see, e.g., Table 1 below). Specifically, provided embodiments can achieve maximum drain currents (Idmax) of greater than or equal to 500 micro-Amps (uA) per micron (um)+/−10%, and the mobility of various embodiments can be greater than 50+/−10% cm2 per volt-second.

With reference to Table 1 below, example median results for ten devices are presented to underscore this performance improvement. Table 1 shows performance of field effect transistors fabricated from 2D material doped with Rhenium (Re), Phosphorous (P) and Nobium (Nb) during 2D growth. As it is seen, in comparison to the control sample, embodiments exhibited transistor performance that is significantly increased with dopants, especially with Re, where the device mobility exceeds 10. Other suitable dopants include yttrium, bismuth, antimony, scandium, vanadium, tellurium.

TABLE 1

| | | Idmax | Idfwd | VtCC_1nA@Vd = | SSfwd_0.1nA- | SSfwd_10nA- | Mobility |
|---|---|---|---|---|---|---|---|
| Sample | ToFSIMS | (A/um) | (A/um) | 1V | 10nA | 1uA | cm2/Vs |
| 0.3% | 8e14 | 5.24e−5 | 1.96e−5 | 1.61 | 2919 | 5092 | 10.37 |
| Re | atoms/cm2 | | | | | | |
| 0.3% | Not | 5.17e−5 | 1.85e−5 | 4.14 | 3634 | 5105 | 8.93 |
| P | detected | | | | | | |
| 0.3% | Not | 1.5e−05 | 5.28e−6 | −0.26 | 4030 | 8132 | 3.52 |
| Nb | detected | | | | | | |
| Control | 0 | 973e−7 | 2.94e−7 | −31.7 | 5843 | 8555 | — |
| POR | — | 9.36e−6 | 4.15e−6 | −16.89 | 6304 | 9217 | 0.8 |

FIGS. 6-13 illustrate architectures and devices that may incorporate embodiments described herein.

FIG. 6A is a perspective view of an example planar field effect transistor (FET) 600 comprising a gate 602, a source region 604, and a drain region 606. The planar FET 600 is formed on a substrate 616 comprising a surface 608, a bulk region 618, and isolation regions 614 that separate the source and drain regions 604 and 606 from other transistors. In various embodiments, a gallium enriched layer 619 may be positioned between the source region 604 and a source contact metal 617 (shown in FIG. 6B) and a gallium enriched layer 621 may be positioned between the drain region 606 and a drain contact metal (not shown). The planar FET 600 is planar in that the source region 604 and the drain region 606 are planar with respect to the surface 608 of the substrate 616. FIG. 6B is a cross-sectional view 640 of the planar FET 600 taken along the source contact region of planar FET 600. Cross-sectional view 640 illustrates a source contact metal 617 located above the source region 604, with the gallium enriched layer 619 positioned between the source contact metal 617 and the source region 604. The 2D material described above, in which the doped source region, the channel, and the doped drain region are found, may extend to the depth 622 within the oxide or substrate 616.

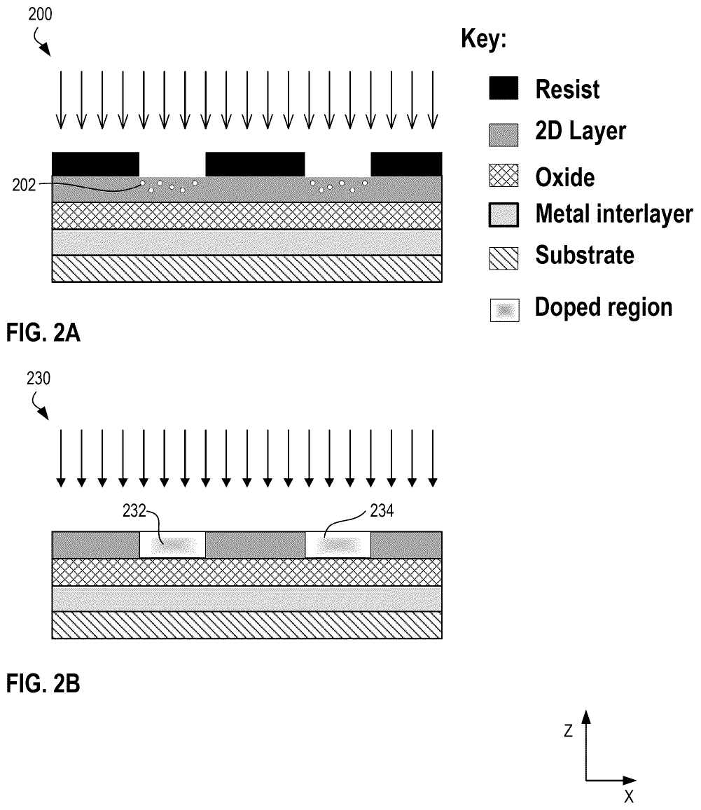

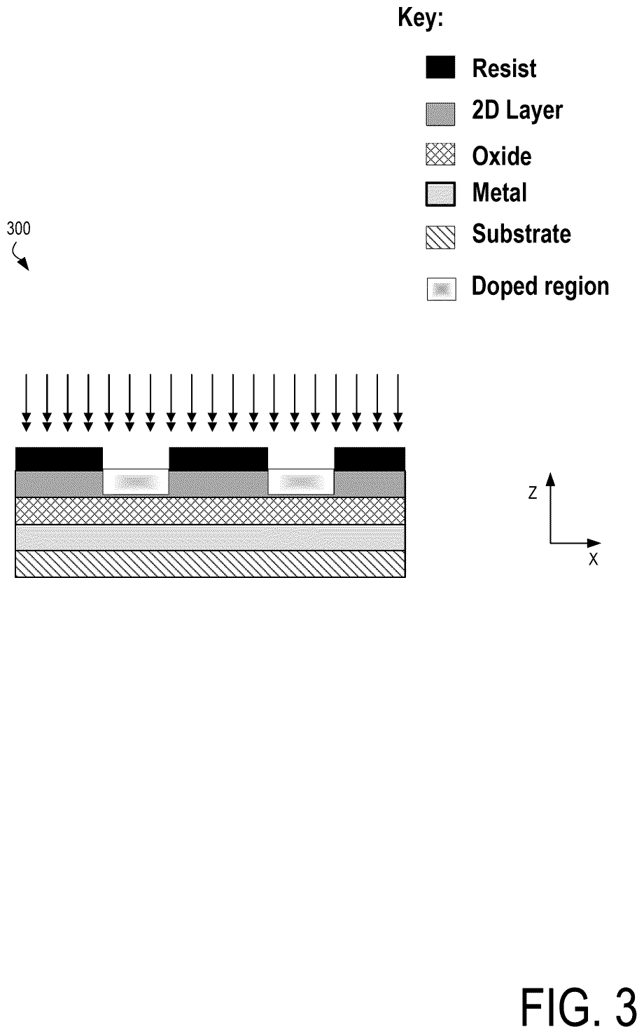

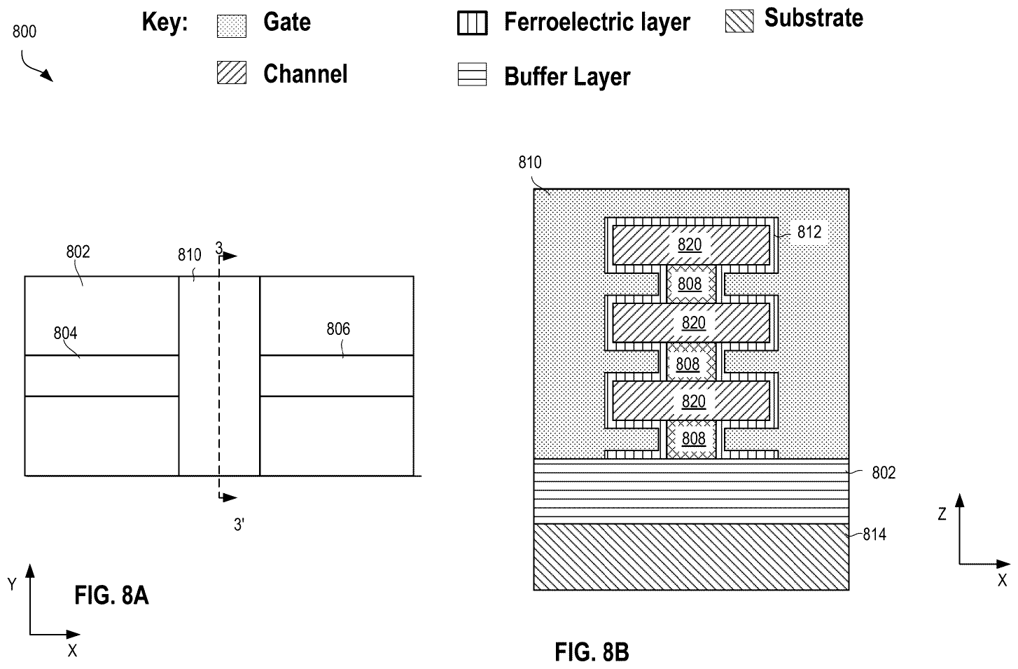

Referring now to FIGS. 7, 8A and 8B, FIG. 7 shows a perspective view of a ribbon FET 700, FIG. 2 shows a top-down view of the ribbon FET 700, and FIG. 3 shows a cross-sectional view of the ribbon FET 700. The ribbon FET 700 may also be referred to as a gate-all-around transistor, a nanowire transistor, a nanosheet transistor, etc. The ribbon FET 700 has one or more source fins 704/804 and one or more drain fins 706/806. Spacers 708/808 may be interleaved with the fins 704/804, 706/806. In various embodiments, a layer 712/812 may surround a channel region 302 of the fins 704/804, 706/806. In some scenarios, the layer 712/812 can comprise a ferroelectric material, and in other scenarios, the layer 712/812 can be a dielectric or insulating material. A gate 710/810 surrounds the layer 712/812.

In the illustrative embodiment, the substrate 714 supports the buffer layer 702 and the rest of the transistor 700. As described in connection with FIGS. 1-4, the substrate 714 may be silicon, silicon oxide, gallium nitride, etc. The buffer layer 702 may be any suitable material on which the spacers 708 and/or the fins 704, 706 may be grown.

The transistor embodiment 700 may include and suitable number of source fins 704/804 and drain fins 706/806, such as 1-10. Consistent with the above, a compositional analysis of the source fins 704/804, the drain fins 706/806, and the intervening channel 820 of the FET would reveal a 2D material, and further, that the 2D material has been doped in the source region and the drain region, also as described above. The spacers 708/808 may comprise silicon nitride (SiN) or another suitable semiconductor or can be made from an insulator material.

In various scenarios, processing steps can include growing the channel 820, causing vacancies in the S/D fins, doping vacancies in the S/D fins, and growing the spacer 708/808 in alternating layers as a stack. The undoped semiconductor or insulator can be preferentially etched, forming the fins 704, 706 and leaving spacers 708. The optional ferroelectric layer 712/812 may be any suitable ferroelectric material and may be any suitable thickness, such as a thickness of about 0.5-25 nanometers.

The illustrative gate 710 may comprise materials, such as platinum, antimony, bismuth, iridium, copper, aluminum, or other metal, oxides with high electric conductivity, including RuO2, IrO2, and ITO, polysilicon, etc.

Thus, architectures and methods to modulate contact resistance in 2D material for use in field effect transistor devices have been described. To summarize, unique features of this disclosure include distinct stoichiometry compositions as well as notably improved performance and mobility. The following description and associated figures provide more detail for components referenced hereinabove.

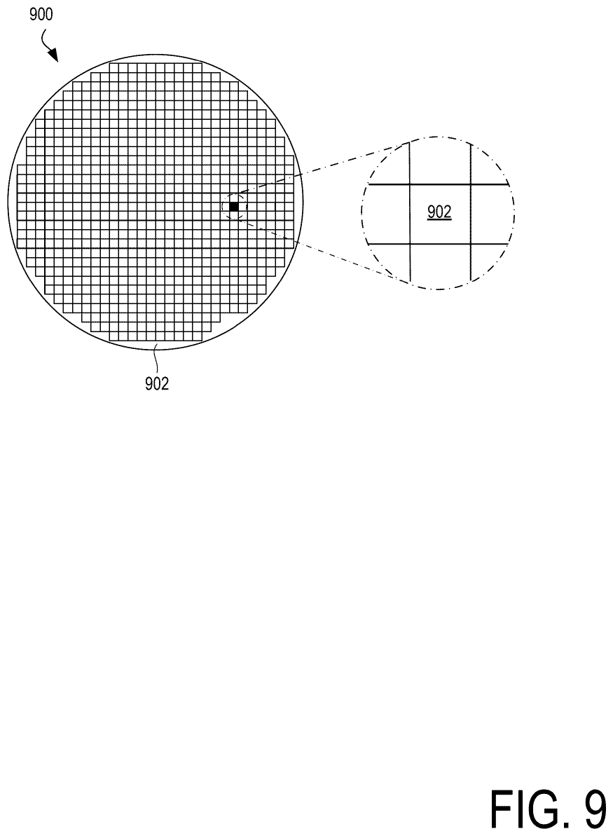

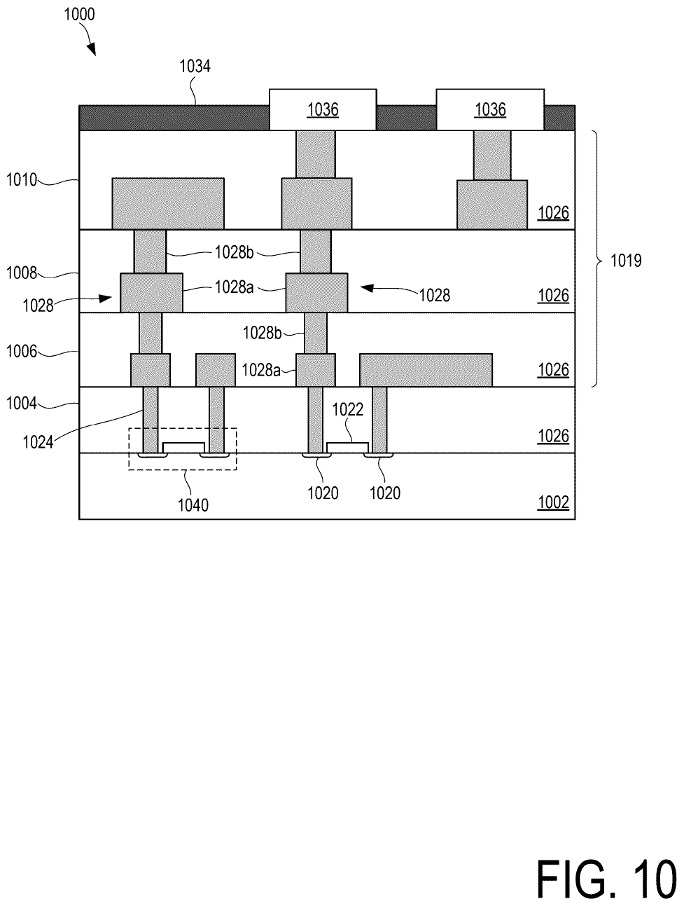

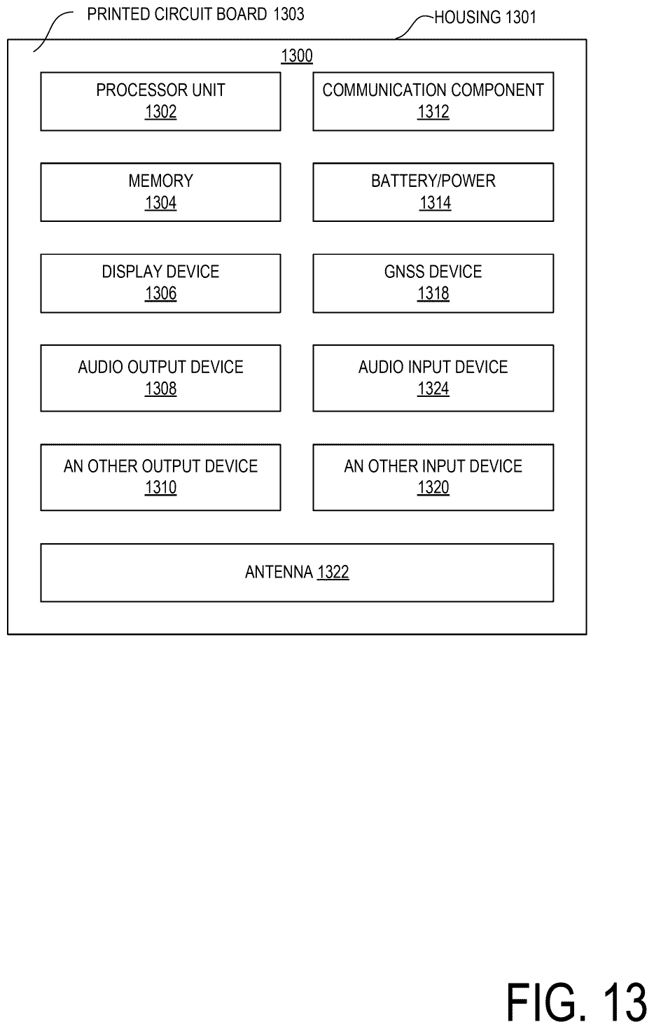

FIG. 9 is a top view of a wafer 900 and dies 902 that may be included in any of the embodiments disclosed herein. The wafer 900 may be composed of semiconductor material and may include one or more dies 902 formed on a surface of the wafer 900. After the fabrication of the integrated circuit components on the wafer 900 is complete, the wafer 900 may undergo a singulation process in which the dies 902 are separated from one another to provide discrete “chips” or destined for a packaged integrated circuit component. The individual dies 902, comprising an integrated circuit component, may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. In some embodiments, a die 902 may be attached to a wafer 900 that includes other die, and the wafer 900 is subsequently singulated, this manufacturing procedure is referred to as a die-to-wafer assembly technique.

FIG. 10 is a cross-sectional side view of an integrated circuit 1000 that may be included in any of the embodiments disclosed herein. One or more of the integrated circuits 1000 may be included in one or more dies 902 (FIG. 9). The integrated circuit 1000 may be formed on a die substrate 1002 (e.g., the wafer 900 of FIG. 9) and may be included in a die (e.g., the die 902 of FIG. 9).

The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit 1000 may be used. The die substrate 1002 may be part of a singulated die (e.g., the dies 902 of FIG. 9) or a wafer (e.g., the wafer 900 of FIG. 9).

The integrated circuit 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020.

The gate 1022 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be conducted to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, phosphorous, yttrium, bismuth, antimony, scandium, vanadium, tellurium. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuits having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028a/b of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit 1000 with another component (e.g., a printed circuit board). The integrated circuit 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit 1000 is a double-sided die, the integrated circuit 1000 may include another metallization stack (not shown) on the opposite side of the device layer(s) 1004. This metallization stack may include multiple interconnect layers as discussed above with reference to the interconnect layers 1006-1010, to provide electrically conductive paths (e.g., including conductive lines and vias) between the device layer(s) 1004 and additional conductive contacts (not shown) on the opposite side of the integrated circuit 1000 from the conductive contacts 1036.

In other embodiments in which the integrated circuit 1000 is a double-sided die, the integrated circuit 1000 may include one or more through-silicon vias (TSVs) through the die substrate 1002; these TSVs may make contact with the device layer(s) 1004, and may provide electrically conductive paths between the device layer(s) 1004 and additional conductive contacts (not shown) on the opposite side of the integrated circuit 1000 from the conductive contacts 1036. In some embodiments, TSVs extending through the substrate can be used for routing power and ground signals from conductive contacts on the opposite side of the integrated circuit 1000 from the conductive contacts 1036 to the transistors 1040 and any other components integrated into the die of the integrated circuit 1000, and the metallization stack 1019 can be used to route I/O signals from the conductive contacts 1036 to transistors 1040 and any other components integrated into the die of the integrated circuit 1000.

Multiple integrated circuits 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

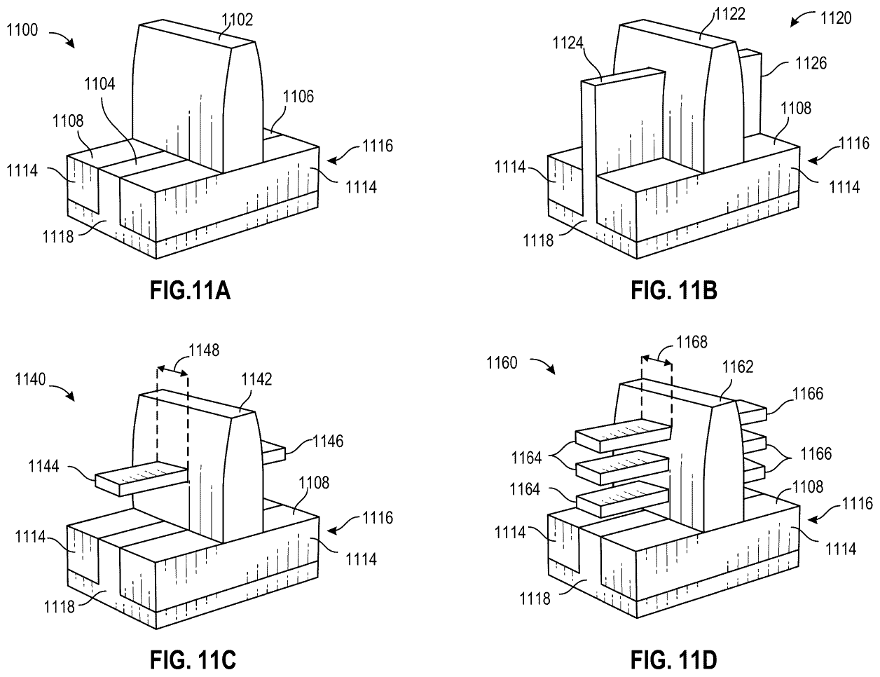

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1108. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1108.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extend from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

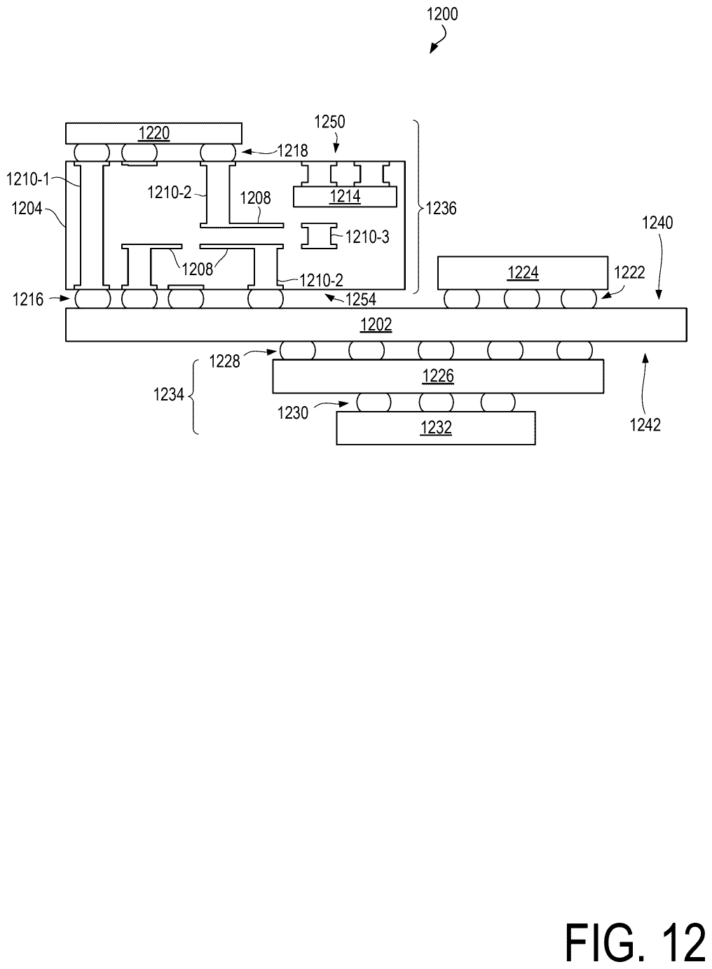

FIG. 12 is a cross-sectional side view of a microelectronic assembly 1200 that may include any of the embodiments disclosed herein. The microelectronic assembly 1200 includes multiple integrated circuit components disposed on a circuit board 1202 (which may be a motherboard, system board, mainboard, etc.). The microelectronic assembly 1200 may include components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The microelectronic assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit component that includes one or more integrated circuit dies (e.g., the die 902 of FIG. 9, the integrated circuit 1000 of FIG. 10) and/or one or more other suitable components.

The unpackaged integrated circuit component 1220 comprises solder bumps attached to contacts on the die. The solder bumps allow the die to be directly attached to the interposer 1204. In embodiments where the integrated circuit component 1220 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through-silicon vias (TSV) extending through the silicon interposer can connect connections on the first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the embodiments disclosed herein. For example, any suitable ones of the components of the electrical device 1300 may include one or more of the disclosed embodiments, semiconductor assemblies, package assemblies, microelectronic assemblies 1200, integrated circuit components 1220, integrated circuits 1000, integrated circuit dies 902, or structures disclosed herein, attached on a printed circuit board 1301. A number of components are illustrated in FIG. 13 as included in the electrical device 1300, but any one or more of these components may be omitted or duplicated, as suitable for the application. In some embodiments, some or all the components included in the electrical device 1300 may be attached to one or more motherboards, mainboards, printed circuit boards, or system boards. In some embodiments, one or more of these components are fabricated onto a single system-on-a-chip (SoC) die. In various embodiments, the electrical device 1300 is enclosed by, or integrated with, a housing 1303.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1300 can comprise one or more processor units 1302 that are heterogeneous or asymmetric to another processor unit 1302 in the electrical device 1300. There can be a variety of differences between the processor units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include power supply such as a battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include another output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a field effect transistor comprising: a first layer comprising oxide over a second layer of substrate material; a channel material comprising transition metal atoms and chalcogen atoms overlaid on the first layer; and a region in the channel material comprising less than or equal to 10% dopant atoms, and wherein the dopant atoms comprise fluorine, rhenium, niobium, tantalum, oxygen, or phosphorus.

Example 2 includes the subject matter of Example 1, wherein the channel material is a two-dimensional (2D) material.

Example 3 includes the subject matter of Example 1, wherein the channel material is between 0.7 and 2.8 nanometers thick.

Example 4 includes the subject matter of any one of Example 1-Example 3, wherein the transition metal atoms comprise molybdenum or tungsten.

Example 5 includes the subject matter of Example 4, wherein the channel material comprises WSe2, MoS2, MoTe2, or WS2.

Example 6 includes the subject matter of any one of Examples 1-5, further comprising a first source/drain metal contact attached to the region.

Example 7 includes the subject matter of Example 6, wherein a contact resistance measured between the first source/drain metal contact and the region is less than 100 ohm/micrometer.

Example 8 includes the subject matter of Example 6, wherein a maximum drain current (Idmax) measured for the field effect transistor is greater than or equal to500 micro-Amps per micron.

Example 9 includes the subject matter of any one of Examples 1-8, further comprising a ferroelectric layer surrounding the channel material.

Example 10 includes the subject matter of Example 1, further comprising a metal layer between the oxide and the substrate, the metal layer to be a back-gate.

Example 11 includes the subject matter of any one of Examples 1-10, further comprising an integrated circuit die comprising the field effect transistor.

Example 12 is an apparatus comprising: a complementary metal oxide semiconductor (CMOS) circuit comprising: a P-type field effect transistor (FET); and an N-type FET comprising: a channel material comprising transition metal atoms and chalcogen atoms; and a region in the channel material comprising less than or equal to 3% dopant atoms, and wherein the dopant atoms comprise niobium, tantalum, oxygen, or phosphorus.

Example 13 includes the subject matter of Example 12, wherein the P-type FET and N-type FET comprise respective drains coupled together, and respective gates coupled together.

Example 14 includes the subject matter of Example 12 or Example 13, wherein the P-type FET comprises a p-channel, and further comprises a ferroelectric material surrounding the channel material and the p-channel.

Example 15 includes the subject matter of any one of Examples 12-14, wherein the CMOS circuit is operable to function as either a memory element or a logic element dependent on one or more bias voltages applied to the circuit.

Example 16 is a method comprising: forming an oxide layer over a substrate; forming a two-dimensional (2D) channel material on the substrate, the channel material comprising transition metal atoms and chalcogen atoms; identifying, for a plurality of field effect transistors, respective source/drain locations in the 2D channel material; causing vacancies in the 2D channel material at the respective source/drain locations; introducing dopant atoms at the vacancies, wherein dopant atoms comprise less than 3% of the channel material; and attaching source/drain contact metal to the respective source/drain locations.

Example 17 includes the subject matter of Example 16, wherein causing vacancies in the 2D channel material is achieved with a plasma comprising one or more of (H) hydrogen, (NH3) ammonia, (O2) oxygen, and (CF4) carbon tetrafluoride.

Example 18 includes the subject matter of Example 16, wherein introducing dopant atoms at the vacancies is achieved with a plasma comprising one or more of comprises nitric oxide (NOx), phosphorous (P), vanadium (V), sulfur(S), or fluorine (F).

Example 19 includes the subject matter of Example 16, wherein introducing dopant atoms at the vacancies is achieved with a plasma comprising one or more of niobium (Nb) or tantalum (Ta).

Example 20 includes the subject matter of Example 16, further comprising surrounding the channel material with a ferroelectric material.

What is claimed is:

1. An apparatus, comprising:
a field effect transistor comprising:
a first layer comprising oxide over a second layer of substrate material;
a channel material comprising transition metal atoms and chalcogen atoms overlaid on the first layer; and
a region in the channel material comprising less than or equal to 10% dopant atoms, and wherein the dopant atoms comprise fluorine, rhenium, niobium, tantalum, oxygen, or phosphorus.

2. The apparatus of claim 1, wherein the channel material is a two-dimensional (2D) material.

3. The apparatus of claim 1, wherein the channel material is between 0.7 and 2.8 nanometers thick.

4. The apparatus of claim 1, wherein the transition metal atoms comprise molybdenum or tungsten.

5. The apparatus of claim 1, wherein the channel material comprises WSe₂, MoS₂, MoTe₂, or WS₂.

6. The apparatus of claim 1, further comprising a first source/drain metal contact attached to the region.

7. The apparatus of claim 6, wherein a contact resistance measured between the first source/drain metal contact and the region is less than 100 ohm/micrometer.

8. The apparatus of claim 6, wherein a maximum drain current (Idmax) measured for the field effect transistor is greater than or equal to500 micro-Amps per micron.

9. The apparatus of claim 1, further comprising a ferroelectric layer surrounding the channel material.

10. The apparatus of claim 1, further comprising a metal layer between the oxide and the substrate, the metal layer to be a back-gate.

11. The apparatus of claim 1, further comprising an integrated circuit die comprising the field effect transistor.

12. An apparatus comprising:
a complementary metal oxide semiconductor (CMOS) circuit comprising:
a P-type field effect transistor (FET); and
an N-type FET comprising:
a channel material comprising transition metal atoms and chalcogen atoms; and
a region in the channel material comprising less than or equal to 3% dopant atoms, and wherein the dopant atoms comprise niobium, tantalum, oxygen, phosphorus, yttrium, bismuth, antimony, scandium, vanadium, tellurium.

13. The apparatus of claim 12, wherein the P-type FET and N-type FET comprise respective drains coupled together, and respective gates coupled together.

14. The apparatus of claim 12, wherein the P-type FET comprises a p-channel, and further comprising a ferroelectric material surrounding the channel material and the p-channel.

15. The apparatus of claim 12, wherein the CMOS circuit is operable to function as either a memory element or a logic element dependent on one or more bias voltages applied to the circuit.

16. A method comprising:
forming an oxide layer over a substrate;
forming a two-dimensional (2D) channel material on the substrate, the channel material comprising transition metal atoms and chalcogen atoms;
identifying, for a plurality of field effect transistors, respective source/drain locations in the 2D channel material;
causing vacancies in the 2D channel material at the respective source/drain locations;
introducing dopant atoms at the vacancies, wherein dopant atoms comprise less than 3% of the channel material; and
attaching source/drain contact metal to the respective source/drain locations.

17. The method of claim 16, wherein causing vacancies in the 2D channel material is achieved with a plasma comprising one or more of (H) hydrogen, (NH3) ammonia, (O2) oxygen, and (CF4) carbon tetrafluoride.

18. The method of claim 16, wherein introducing dopant atoms at the vacancies is achieved with a plasma comprising one or more of comprises nitric oxide (NOx), phosphorous (P), vanadium (V), sulfur(S), or fluorine (F).

19. The method of claim 16, wherein introducing dopant atoms at the vacancies is achieved with a plasma comprising one or more of niobium (Nb) or tantalum (Ta).

20. The method of claim 16, further comprising surrounding the channel material with a ferroelectric material.
